(19) United States
(12) Patent Application Publication
(10) Pub. No.: US 2025/0041988 A1
(43) Pub. Date: Feb. 6, 2025

(54) DEVICE FOR MEASURING WAFER POLISHING AMOUNT, AND MEASUREMENT METHOD THEREFOR

(71) Applicant: SK SILTRON CO., LTD., Gumi-si, Gyeongsangbuk-do (KR)

(72) Inventor: Sangho LEE, Gumi-si (KR)

(21) Appl. No.: 18/717,802

(22) PCT Filed: Apr. 13, 2022
(86) PCT No.: PCT/KR2022/005337

§ 371 Date: Jun. 7, 2024

(30) Foreign Application Priority Data
Dec. 7, 2021 (KR) 10-2021-0173597

(51) Int. Cl. B24B 49/03; B24B 37/005; B24B 37/34; G01G 19/52; H01L 21/66

(52) U.S. Cl. CPC B24B 49/03; B24B 37/005; B24B 37/345; H01L 22/12; G01G 19/52

(57) ABSTRACT

An embodiment of the present invention provides a device for measuring a wafer polishing amount, comprising: a first weighing unit for measuring the weight of a loading cassette in which wafers are accommodated before polishing; a second weighing unit for measuring the weight of an unloading cassette in which the wafers are stored after polishing; and a control unit for calculating the polishing amount of the wafers before/after polishing according to measurement values of the first and second weighing units.

### TECHNICAL FIELD

The present invention relates to a device for manufacturing a wafer polishing amount, which is capable of precisely measuring and managing the wafer polishing amount, and a measurement method thereof.

### BACKGROUND ART

In general, a wafer, which is widely used as a material for manufacturing semiconductor elements, refers to a single-crystalline silicon thin plate made from polycrystalline silicon as a raw material.

Such a wafer is manufactured through a slicing process of growing polycrystalline silicon into a single crystal silicon ingot and then cutting the silicon ingot in the form of a wafer, a lapping process of uniformizing a thickness of the wafer so that the wafer is flat, an etching process of removing and alleviating damage caused by mechanical polishing, a polishing process of mirroring a surface of the wafer, and a cleaning process of cleaning the wafer.

The polishing process is a very important process because the polishing process is a process of generating final flatness and surface roughness before the wafer is introduced into the device process.

In the polishing process, the wafer adsorbed on a head rotates under a pressure on a polishing pad so that the surface of the wafer is mechanically planarized, and also, slurry that performs a chemical reaction onto the polishing pad is supplied so that the surface of the wafer is chemically planarized.

A double-sided polishing device for a wafer, which measures a thickness of a central portion of the wafer and enables highly reliable thickness measurement is disclosed in Japanese Patent Application No. 2007-066964 (published on Sep. 25, 2008).

When a window is formed on a top plate, and the top plate rotates, a thickness measuring device is disposed on a support frame disposed at an upper portion of the window that passes therethrough. The thickness measuring device includes a light emitting part that emits laser light toward the window, an objective lens that moves by a driving device to focus the laser light emitted from the light emitting part, a light receiving part that receive reflected light reflected to the surface and a rear surface of the wafer, and a calculation part in which a light receiving signal is input from the light receiving part to calculate a thickness of the wafer from a peak value of each reflected light on the surface and the rear surface of the wafer.

According to the related art, although an optical thickness measuring device is disposed in the polishing device to measure the polishing amount of the wafer in real time, since the polishing amount of the wafer through the polishing process is so small, even if the polishing amount is optically measured, discriminative ability that is capable of classifying resolution is deteriorated.

As described above, since the polishing amount of the wafer is not precisely measured enough to meet polishing precision of the polishing process, it is difficult to accumulate data of the polishing amount of the wafer so as to manage the polishing process, and there is a problem that defects or flatness quality of the wafer are not improved after the polishing process.

### DISCLOSURE OF THE INVENTION

### Technical Problem

The present invention has been made to solve the above-described problem of the related art, and an object of the prevent invention is to provide a device for measuring a polishing amount of a wafer, which is capable of precisely measuring and managing the polishing amount of the wafer, and a measuring method thereof.

### Technical Solution

An embodiment of the present invention provides a device for measuring a wafer polishing amount, the device including: a first weighting unit configured to measure a weight of a loading cassette before/after wafers are accommodated before polishing; a second weighting unit configured to measure a weight of an unloading cassette before/after the wafers are accommodated after the polishing; and a control unit configured to calculate a polishing amount of one sheet of wafer according to the measurement values of the first and second weighting units.

The first weighting unit may be configured as a load cell that supports the loading cassette.

The second weighting unit may be configured as a load cell that supports the unloading cassette.

The first weighting unit may measure weights (first and second measurement values) of the loading cassette before/after one sheet of wafer is accommodated in the loading cassette, and the control unit may calculate a weight of one sheet of wafer before the polishing according to a variation in the first and second measurement values, which are input from the first weighting unit.

The second weighting unit may measure weights (third and fourth measurement values) of the unloading cassette before/after one sheet of wafer is accommodated in the unloading cassette, and the control unit may calculate a weight of one sheet of wafer after the polishing according to a variation in the third and fourth measurement values, which are input from the second weighting unit.

The control 1 unit may include a calculation part configured to calculate a polishing amount of one sheet of wafer according to the variation in weight of the wafer before/after the polishing.

The control unit may include a command part configured to compare the polishing amount of the wafer with a target polishing amount to generate a control signal for a next polishing process.

The command part may generate control signals for a polishing pressure, a polishing rotation speed, a polishing time, and a slurry supply amount.

An embodiment of the present invention provides a method for measuring a polishing amount of a wafer, the method including: a first step of measuring a weight of a loading cassette before/after wafers are accommodated before polishing; a second step of measuring a weight of an unloading cassette before/after the wafer are accommodated after the polishing; and a third step of calculating a polishing amount of one sheet of wafer according to the measurement values in the first and second steps.

The first step may include a process of performing the measurement by a load cell that supports the loading cassette.

The second step may include a process of performing the measurement by a load cell that supports the unloading cassette.

The first step may include a process of measuring weights (first and second measurement values) of the loading cassette before/after the one sheet of wafer is accommodated in the loading cassette, and the third step may include a first process of calculating a weight of the one sheet of wafer before the polishing according to a variation in the first and second measurement values, which are input in the first step.

The second step may include a process of measuring weights (third and fourth measurement values) of the unloading cassette before/after the one sheet of wafer is accommodated in the unloading cassette, and the third step may include a second process of calculating a weight of the one sheet of wafer after the polishing according to a variation in the third and fourth measurement values, which are input in the second step.

The third step may further include a third process of calculating a polishing amount of the one sheet of wafer according to the variation in weight of the one sheet of wafer before/after the polishing, which is calculated in the first and second processes.

The third step may further include a fourth process of comparing the polishing amount of the wafer, which is calculated in the third process, with a target polishing amount to generate a control signal for a next polishing process.

In the fourth process, control signals for a polishing pressure, a polishing rotation speed, a polishing time, and a slurry supply amount may be generated.

### Advantageous Effects

In the device of the measuring the polishing amount of the wafer and the measuring method thereof according to the present embodiment, the weights of the loading cassette and the unloading cassette may be precisely measured using the load cell, and the fine polishing amount of the wafer may be accurately calculated through the change in weight of the unloading cassette and the change in weight of the loading cassette.

In addition, the polishing amount of each wafer may be accumulated and managed as data to generate the control signals according to the polishing amount of the wafer, thereby controlling the polishing process in real time, and the defects or flatness quality of the wafer, which may occur in the polishing process, may be effectively improved.

### BRIEF DESCRIPTION OF THE DRAWINGS

FIG. 1 is a view illustrating a wafer polishing device according to the present embodiment.

FIG. 2 is a schematic view illustrating a device for measuring a polishing amount of a wafer, which is applied to FIG. 1.

FIG. 3 is a flowchart illustrating a method for measuring a polishing amount of a wafer according to the present embodiment.

### MODE FOR CARRYING OUT THE INVENTION

Hereinafter, exemplary embodiments will be described in detail with reference to the accompanying drawings.

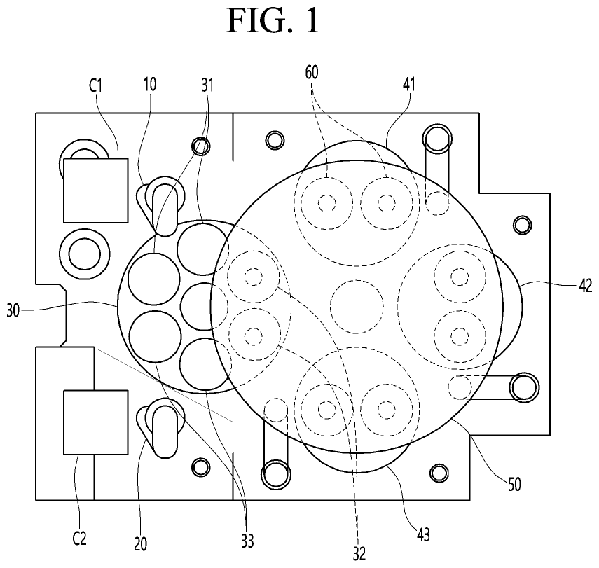

FIG. 1 is a view illustrating a wafer polishing device according to the present embodiment.

As illustrated in FIG. 1, a wafer polishing device according to the present embodiment includes a loading robot 10, an unloading robot 20, a transfer 30 through which a wafer moves, first, second, and third polishing plates 41, 42, and 43 on which the wafer is polished, an index 50 rotatably provided above the transfer 30 and the first, second, and third polishing plates 41, 42, and 43, and a plurality of polishing heads 60 elevatably and rotatably provided below the index 50.

The loading robot 10 allow wafers accommodated in a loading cassette C1 one by one to move to the transfer 30 before proceeding with the polishing process.

After performing the polishing process, the unloading robot 20 allow the wafers seated on the transfer 30 one by one to move to an unloading cassette C2.

The transfer 30 may be a circular shelf, on which the wafers are seated, be rotatably installed, and includes a loading part 31, a detachment part 32, and an unloading part 33, on which a pair of wafers are seated, respectively.

The loading part 31 may provide a space in which the pair of wafers moving from the loading cassette C1 by the loading robot 10 are seated. Whenever the transfer 30 rotates, the wafers seated in the loading part 31 move to the detachable part 32.

The detachment part 32 may provide a space in which the pair of wafers are detached from the pair of polishing heads 60 so as to perform the polishing process. Whenever, the transfer 40 rotates, the wafers seated on the detachment part 32 move to the unloading part 33.

The unloading part 33 may provide a space in which the pair of wafers to be moved to the unloading cassette C2 by the unloading robot 20 are seated. Whenever, the transfer 30 rotate, the empty space at a side of the unloading part 33 moves to the loading part 31.

The transfer 30 and three polishing plates 41, 42, and 43 are disposed in all directions.

The first, second, and third polishing plates 41, 42, and 43 are rotatable shelves, and the polishing pad for polishing the wafer is attached to a top surface of each plate.

The index 50 is rotatably installed above the transfer-side detachment part 32 and the first, second, and third polishing plates 41, 42, and 43. A pair of polishing heads 60 are provided at positions opposite to the polishing plates 41, 42, and 43, respectively.

Whenever the index 50 rotates, the pair of polishing heads 60 disposed at an upper side of the transfer-side detachment part 32 move to an upper side of the first polishing plate 41, the pair of polishing heads 60 disposed at the upper side of the first polishing plate 41 move to an upper side of the second polishing plate 42, the pair of polishing heads 60 disposed at the upper side of the second polishing plat 42 move to an upper side of the third polishing plate 43, and the pair of polishing heads 60 disposed at the upper side of the third polishing plate 43 move to an upper side of the transfer-side detachment part 32.

The polishing head 60 is rotatably and elevatably installed on a bottom surface of the index 50 so that the wafer is adsorbed on the bottom surface of the polishing head 60. Thus, whenever the index 50 rotates, the wafer adsorbed on the polishing head 60 sequentially moves along the transfer-side detachment part 32 and the first, second, and third polishing plates 41, 42, and 43.

The wafer polishing device configured as described above may control a polishing pressure, a polishing rotation speed, a polishing time, a slurry supply amount, and the like. The polishing amount of the wafer during the polishing process may be precisely measured and stored using the device for measuring the polishing amount of the wafer, which will be described below, and thus, the polishing amount of the wafer in the current process may be reflected to control a next process.

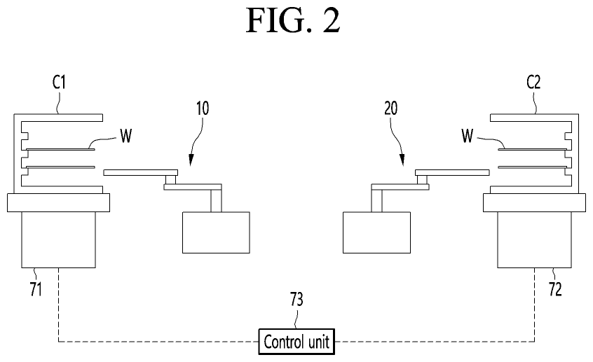

FIG. 2 is a view illustrating a device for measuring a polishing amount of a wafer, which is applied to FIG. 1.

The device for measuring the polishing amount of the wafer according to the present embodiment includes a first weighting unit 71 that measures a weight of the loading cassette C1, a second weighting unit 72 that measures a weight of the unloading cassette C2, and a control unit 73 that calculates a polishing amount of the wafer according to the measured values of the first and second weighting units 71 and 72.

The first weighting unit 71 may be provided in the form of a load cell capable of measuring a weight up to lug and may be configured to support the loading cassette C1, but is not limited thereto.

The first weighting unit 71 may measure the weight of the loading cassette C1 whenever the wafers W are loaded one by one from the loading cassette C1 to the transfer 30 before the polishing, and the weight measurement value may be transmitted to the control unit 73. The first weighting unit 71 may measure a weight of the loading cassette C1 as a first measurement value before the wafer W is loaded, i.e., in a state in which the wafer is present as it is, and after one sheet of wafer W is loaded, i.e., in a state in which the wafer W is absent, the first weighting unit 71 may measure a weight of the loading cassette C1 as a second measurement value, and then, the first and second measurement values may be transmitted to the control unit 73.

Like the first weighting unit 73, the second weighting unit 72 may be provided in the form of a load cell that is capable of measuring a weight up to 1 μg and may be configured to support the unloading cassette C2, but is not limited thereto.

The second weighting unit 72 may measure a weight of the unloading cassette C2 whenever the wafers W are unloaded one by one from the transfer 30 to the unloading cassette C2 after the polishing, and then, the weight measurement value of the unloading cassette C2 may be transmitted to the control unit 73. The second weighting unit 72 may measure a weight of the unloading cassette C2 as a third measurement value before the wafer W is unloaded, i.e., in a state in which the wafer is absent, and after one sheet of wafer W is unloaded, i.e., in a state in which the wafer W is present as it is, the second weighting unit 72 may measure a weight of the unloading cassette C2 as a fourth measurement value, and then, the third and fourth measurement values may be transmitted to the control unit 73.

When the first and second weighting units 71 and 72 are configured as the load cells, the two load cells may measure the same weight to periodically calibrate the measured value so as to increase in accuracy of the measured value.

For example, the measured values of the first and second weighting units 71 and 72 may be corrected to within ±3% and may be precisely corrected to within ±10 nm based on the polishing amount of the wafer.

The control unit 73 may include a calculation part that calculates the polishing amount of each wafer in the current process through the measurement values transmitted from the first and second weighting units 71 and 72, a storage part that stores the polishing amount of each wafer for the polishing process, and a command part that generates a control signal of a next process in consideration of the polishing amount of the wafer in the current process.

Looking at an operation of the control unit 73, whenever the first and second measurement values are input from the first weighting unit 71, the calculation part may calculate the weight of the wafer before the polishing through variations of the first and second measurement values, and whenever the third and fourth measurement values are input from the second weighting unit 72, the calculation part may calculate the weight of the wafer after the polishing through variations of the third and fourth measurement values, and then, the polishing amount of the wafer may be calculated through the change in weight of the wafer before/after the polishing.

As described above, the calculated polishing amount of each wafer may be stored and managed as data in the storage part, and the command part may generate control signals for controlling the polishing pressure, the polishing rotation speed, the polishing time, and the slurry supply amount in consideration of the polishing amount of the wafer in the current process, thereby controlling the polishing amount of the wafer in real time in the next process.

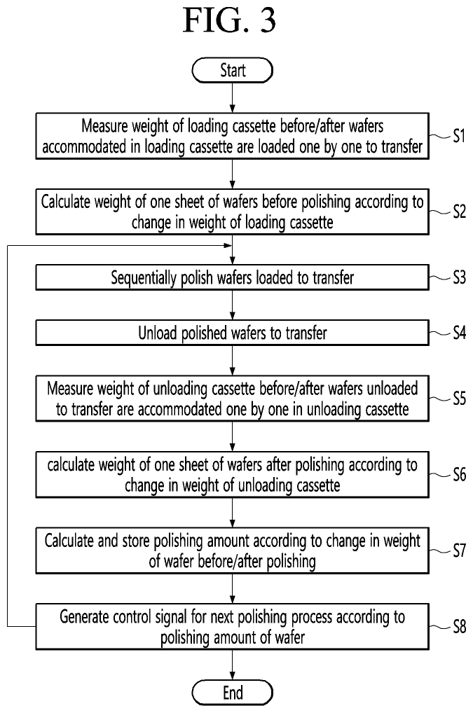

FIG. 3 is a flowchart illustrating a method for measuring a polishing amount of a wafer according to the present embodiment.

Referring to FIGS. 1 to 3, a weight of a loading cassette C1 is measured before/after wafers accommodated in a loading cassette C1 are loaded one by one to a transfer 30 (see S1).

When the loading cassette C1 that accommodates the wafers W to be polished is provided at a loading position, a first weighting unit 71 measures a weight of the loading cassette C1 as a first measurement value, and a loading robot 10 loads the wafers W1 accommodated in the loading cassette C1 one by one to a loading part 31 of the transfer, and then, the first weighting unit 71 measures a weight of the loading cassette C1 as a second measurement value. As described above, the first weighting unit 71 repeats the process of measuring the weight of the loading cassette C1.

Next, the weight of one sheet of wafer before the polishing is calculated according to a change in weight using the loading cassette C1 (see S2).

The control unit 73 may calculate a difference between the first and second measurement values input from the first weighting unit 71 as the weight of one wafer and then store and manage the weight of each wafer before the polishing.

Next, the wafers W loaded on the transfer 30 may be sequentially polished, and the polished wafer W may be unloaded on the transfer 30 (see S3 and S4).

As the transfer 30 rotates, the pair of wafers W loaded in the loading part 31 move to the detachment part 32, and the pair of wafers W loaded in the detachment part 32 moves along the unloading part 33. Here, the above-described processes are repeatedly performed.

In addition, when a polishing head 60 adsorbs the pair of wafers W disposed on the detachment part 32 of the transfer, the polishing head 60 sequentially polishes the pair of wafers W on plates 4, 42, and 43 while moving as an index 50 rotates, and then, the polishing head 60 moves the pair of polished wafers W again to the detachment part 32 of the transfer. Here, the above-described processes are repeatedly performed.

Particularly, a control signal may be generated in consideration of a polishing amount of the wafer in the previous polishing process to control a polishing pressure, a polishing rotation speed, a polishing time, and a slurry supply amount during the current polishing process, thereby precisely controlling the polishing amount of the wafer in real time.

Next, a weight of the unloading cassette C2 may be measured before/after the wafers W unloaded from the transfer 30 are accommodated in the unloading cassette C2 one by one (see S5).

When the unloading cassette C2 is provided at an unloading position before the wafers W for which the polishing process has been completed are accommodated, the second weighting unit 62 measures a weight of the unloading cassette C2 as a third measurement value, and the unloading robot 20 accommodates the wafers W one by one disposed in the unloading part 33 of the transfer, and then, the second weighting unit 72 measures a weight of the unloading cassette C2 as a fourth measurement value. As described above, the second weighting unit 72 repeats the process of measuring the weight of the unloading cassette C1.

Next, the weight of one sheet of wafer after the polishing may be calculated according to the change in weight of the unloading cassette C2 (see S6).

The control unit 73 may calculate a difference between the third and fourth measurement values input from the second weighting unit 72 as the weight of one wafer and then store and manage the weight of each wafer after the polishing.

Next, the polishing amount may be calculated and stored according to the change in weight of the wafer before/after the polishing (see S7).

The control unit 73 may calculate the polishing amount of the wafer by subtracting the weight of the wafer after the polishing from the weight of the wafer before the polishing, and then may accumulate and store and manage the polishing amount of each wafer as data.

Next, a control signal for the next polishing process may be generated according to the polishing amount of the wafer (see S8).

The control unit 73 may compare the polishing amount of each wafer with a target polishing amount and generate control signals related to a polishing pressure, a polishing rotation speed, a polishing time, and a slurry supply amount of the next process to control the polishing amount of the wafer.

A degree of pressing of the polishing head and a rotation speed and rotation time of the head or plate may be automatically controlled to precisely control the polishing amount of each wafer in real time. In addition, defects or flatness quality of the wafer that may occur during the polishing process may be effectively improved using the accumulated and stored data.

The above-disclosed subject matter is to be considered illustrative, and not restrictive, and the appended claims are intended to cover all such modifications, enhancements, and other embodiments, which fall within the true spirit and scope of the present invention.

Thus, the embodiment of the present invention is to be considered illustrative, and not restrictive, and the technical spirit of the present invention is not limited to the foregoing embodiment.

Therefore, the scope of the present invention is defined not by the detailed description of the invention but by the appended claims, and all differences within the scope will be construed as being comprised in the present invention.

### INDUSTRIAL APPLICABILITY

The present embodiment may be applied to the process of polishing the single-crystalline silicon thin plate to manufacture the polycrystalline silicon wafer.

1. A device for measuring a wafer polishing amount, the device comprising:
a first weighting unit configured to measure a weight of a loading cassette before/after wafers are accommodated before polishing;
a second weighting unit configured to measure a weight of an unloading cassette before/after the wafers are accommodated after the polishing; and
a control unit configured to calculate a polishing amount of one sheet of wafer according to the measurement values of the first and second weighting units.

2. The device according to claim 1, wherein the first weighting unit is configured as a load cell that supports the loading cassette.

3. The device according to claim 1, wherein the second weighting unit is configured as a load cell that supports the unloading cassette.

4. The device according to claim 1, wherein the first weighting unit measures weights (first and second measurement values) of the loading cassette before/after one sheet of wafer is accommodated in the loading cassette, and
the control unit calculates a weight of one sheet of wafer before the polishing according to a variation in the first and second measurement values, which are input from the first weighting unit.

5. The device according to claim 4, wherein the second weighting unit measures weights (third and fourth measurement values) of the unloading cassette before/after one sheet of wafer is accommodated in the unloading cassette, and
the control unit calculates a weight of one sheet of wafer after the polishing according to a variation in the third and fourth measurement values, which are input from the second weighting unit.

6. The device according to claim 5, wherein the control unit includes a calculation part configured to calculate a polishing amount of one sheet of wafer according to the variation in weight of the wafer before/after the polishing.

7. The device according to claim 1, wherein the control unit includes a command part configured to compare the polishing amount of the wafer with a target polishing amount to generate a control signal for a next polishing process.

8. The device according to claim 7, wherein the command part generates control signals for a polishing pressure, a polishing rotation speed, a polishing time, and a slurry supply amount.

9. A method for measuring a polishing amount of a wafer, the method comprising:
a first step of measuring a weight of a loading cassette before/after wafers are accommodated before polishing;
a second step of measuring a weight of an unloading cassette before/after the wafer are accommodated after the polishing; and
a third step of calculating a polishing amount of one sheet of wafer according to the measurement values in the first and second steps.

10. The method according to claim 9, wherein the first step includes a process of performing the measurement by a load cell that supports the loading cassette.

11. The method according to claim 9, wherein the second step includes a process of performing the measurement by a load cell that supports the unloading cassette.

12. The method according to claim 9, wherein the first step includes a process of measuring weights (first and second measurement values) of the loading cassette before/after the one sheet of wafer is accommodated in the loading cassette, and
the third step includes a first process of calculating a weight of the one sheet of wafer before the polishing according to a variation in the first and second measurement values, which are input in the first step.

13. The method according to claim 12, wherein the second step includes a process of measuring weights (third and fourth measurement values) of the unloading cassette before/after the one sheet of wafer is accommodated in the unloading cassette, and
the third step includes a second process of calculating a weight of the one sheet of wafer after the polishing according to a variation in the third and fourth measurement values, which are input in the second step.

14. The method according to claim 13, wherein the third step further includes a third process of calculating a polishing amount of the one sheet of wafer according to the variation in weight of the one sheet of wafer before/after the polishing, which is calculated in the first and second processes.

15. The method according to claim 14, wherein the third step further includes a fourth process of comparing the polishing amount of the wafer, which is calculated in the third process, with a target polishing amount to generate a control signal for a next polishing process.

16. The method according to claim 15, wherein, in the fourth process, control signals for a polishing pressure, a polishing rotation speed, a polishing time, and a slurry supply amount are generated.
